(19) United States
(12) Patent Application Publication
(10) Pub. No.: US 2011/0214723 A1
(43) Pub. Date: Sep. 8, 2011

(54) Dye-Sensitized Solar Cell Using Nitrogen Doped Carbon-Nano-Tube and Method for Manufacturing the Same

(75) Inventors: Jeung-Ku Kang, Daejeon (KR); Ga-In Lee, Daejeon (KR); Weon-Ho Shin, Daejeon (KR); Jae-Joon Lee, Seongnam (KR); Narayan Chandra Deb Nath, Chungju (KR); Subrata Sarker, Chungju (KR)

(73) Assignee: KOREA ADVANCED INSTITUTE OF SCIENCE AND TECHNOLOGY, Daejeon (KR)

(21) Appl. No.: 12/842,674

(22) Filed: Jul. 23, 2010

(30) Foreign Application Priority Data
Mar. 3, 2010 (KR) 2010-0018979

(51) Int. Cl. H01L 31/0288; H01L 31/18

(52) U.S. Cl. 136/255; 438/63; 438/85; 977/742; 257/E31.004

(57) ABSTRACT

Provided are a dye-sensitized solar cell and a method for manufacturing the dye-sensitized solar cell using a carbon nanotube (CNₓ) doped with nitrogen, wherein the dye-sensitized solar cell using the carbon nanotube (CNₓ) doped with nitrogen has an improved conductivity and open circuit voltage as compared to those using the carbon nanotube (CNT) and also a high connectivity between a transparent electrode and an oxide semiconductor

### CROSS-REFERENCE TO RELATED APPLICATIONS

This application claims priority to foreign Patent Application KR 2010-0018979, filed on Mar. 3, 2010, the disclosure of which is incorporated herein by reference in its entirety.

### FIELD OF THE INVENTION

The present invention relates to a dye-sensitized solar cell and a method for manufacturing the same, in which the method comprises (i) forming a carbon nanotube layer by using a nitrogen doped carbon nanotube (CNₓ: carbon nitride nanotube), or (ii) including the a nitrogen doped carbon nanotube (CNₓ) in an oxide semiconductor, which is composed of nano-particles, so that the dye-sensitized solar cell of the present invention has an improved connectivity between a transparent electrode and the oxide semiconductor, as well as an improved recombination in a porous cathode electrode and an improved open circuit voltage as compared to those using the carbon nanotube (CNT).

### BACKGROUND OF THE INVENTION

In recent years, new forms of renewable energy are of much interest due to problems, such as rising oil prices, global warming, exhaustion of fossil energy, nuclear waste disposal, position selection involved in construction of a new power plant and the like. Among others, research and development into solar cells, which is a pollution-free energy source, has actively been progressed.

A solar cell, which is an apparatus converting light energy into electric energy using a photovoltaic effect, is classified into a silicon solar cell, a thin film solar cell, a dye-sensitized solar cell, an organic polymer solar sell, and the like according to constituent materials.

The dye-sensitized solar cell is a kind of a solar cell, which electrochemically generates power by using the absorption ability of solar light of dye, and includes a cathode electrode, a dye, an electrolyte, a counter electrode, a transparent conductive electrode, and the like, on a glass substrate. The cathode electrode is composed of n-type oxide semiconductor having a relatively wide band gap, which is a type of nano porous film and a monolayer of a dye is absorbed on the surface of the oxide semiconductor.

After solar light is incident on the solar cell, an electron near Fermi energy in a dye may absorb the solar energy, and then may be excited to an upper energy level, which is not filled with electrons. At this time, vacancy in a lower energy level, where electrons moved from, are filled again with electrons supplied by ions in an electrolyte. The ion, which provides an electron to the dye may move to a counter electrode as an anode electrode, and then is supplied with an electron.

At this time, the counter electrode of the anode electrode region acts as a catalyst in an oxidation-reduction reaction of the ion in the electrolyte, and acts as a donor of an electron into the ion in the electrolyte through the oxidation-reduction reaction of the surface.

Recently, the research regarding the dye-sensitized solar cell using the carbon-nano tube has been attempting to improve the performance of the solar cell. Generally, the carbon nanotube has a conductivity which is similar to that of metal with a resistivity 10⁻⁴ Ωcm, and its surface area is at least 1000 times higher than that of bulk material. Therefore, recently, the carbon nanotube has been actively researched in the fields of manufacture, use, and application. Specifically, the carbon nanotube has semiconductor properties, in which the tube is not able to properly conduct electricity, and also properties of an electric conductor, such as a metal, depending on its form and size. For this reason, it is believed that the carbon nanotube will be used in various ways, such as the field of a super fiber, a surface material, and the like, as well as all sorts of electronic circuitry, since it is very stable, chemically and mechanically.

However, the research about a conventional carbon nanotube have confirmed that the carbon nanotube can be simply used as a material of a counter electrode of a dye-sensitized solar cell, and the detailed technology about such things is not described in the prior arts. In addition, if the carbon nanotube is coated on an upper portion of a conventional transparent substrate, it can be confirmed that its conductivity is decreased due to decreasing its dispersivity, even though the carbon nanotube itself has an excellent conductivity.

The connectivity between the transparent substrate and the carbon nanotube layer formed on the upper portion of the substrate is also not very high, and the result of this is a shorter life-time of the counter electrode, i.e., the carbon nanotube layer may be separated from the substrate after coating on the substrate. As a result, there is a problem such as falling in an efficiency of the dye-sensitized solar cell.

As set forth above, recently, the industry field using the carbon nanotube needs further research for improving the properties of the surface and increasing the efficiency of the product by improving the connectivity of the surface and improving conductivity as necessary. Improving of the described properties is obtained from stably forming the carbon nanotube layer by further improving it's connectivity with objects and the properties of conductivity by stably coating the carbon nanotube on the substrate or the objects of surface coating, and the like.

Therefore, it is required as follows to use the carbon nanotube on the dye-sensitized solar cell and to provide the preparation method thereof: i) the carbon nanotube should have a high conductivity without decreasing open circuit voltage by structurally controlling an interface state, and ii) the dye-sensitized solar cell should have a high efficiency as a result of assuring excellent connectivity with substrates.

### SUMMARY OF THE INVENTION

In view of the forgoing problems, one aspect of the present invention provides a dye-sensitized solar cell having a high efficiency by improving conductivity and decreasing the drop of open circuit voltage generated from in the case of using a carbon nanotube (CNT) via a process of forming the dye-sensitized solar cell using a nitrogen doped carbon nanotube (CNₓ: carbon nitride nanotube) and a method for manufacturing the same.

Another aspect of the present invention provides a dye-sensitized solar cell having a high efficiency and a high stability of device resulted by improving a connectivity between a transparent electrode and an oxide semiconductor via a process, in which the process includes forming a nano-layer by growing polarity on the surface through a doping of tetraoctylammonium bromide (TOAB) with a carbon nanotube (CNT) or a nitrogen doped carbon nanotube (CNₓ) and a method for manufacturing the same.

The technical problems to be accomplished by this invention are not limited to the foregoing, and others not referred to will be understood by those skilled in the art and apparent from the following description.

One embodiment of the present invention provides a dye-sensitized solar cell that comprises an upper transparent substrate; a transparent electrode formed on an inner surface of the upper transparent substrate; a porous cathode electrode formed on the transparent electrode and comprising an oxide semiconductor and a dye adsorbed on a surface of the oxide semiconductor; a counter electrode formed on a lower transparent substrate as an anode electrode part corresponding to the cathode electrode; and an electrolyte filled between the cathode electrode and the counter electrode; wherein the dye-sensitized solar cell further comprises a nitrogen doped carbon nanotube (CNₓ) layer between the transparent electrode and the porous cathode electrode.

Another embodiment of the present invention provides a dye-sensitized solar cell that comprises an upper transparent substrate; a transparent electrode formed on an inner surface of the upper transparent substrate; a porous cathode electrode formed on the transparent electrode and comprising an oxide semiconductor and a dye adsorbed on a surface of the oxide semiconductor; a counter electrode formed on a lower transparent substrate as an anode electrode part corresponding to the cathode electrode; and an electrolyte filled between the cathode electrode and the counter electrode; wherein the porous cathode electrode comprises the nitrogen doped carbon nanotube (CNₓ).

Another embodiment of the present invention provides a method for manufacturing a dye-sensitized solar cell that includes an upper transparent substrate; a transparent electrode formed on an inner surface of the upper transparent substrate; a porous cathode electrode formed on the transparent electrode and comprising an oxide semiconductor and a dye adsorbed on a surface of the oxide semiconductor; a counter electrode formed on a lower transparent substrate as an anode electrode part corresponding to the cathode electrode; and an electrolyte filled between the cathode electrode and the counter electrode, in which the method comprises (a) preparing the nitrogen doped carbon nanotube (CNₓ); (b) forming a transparent electrode on the inner surface of the upper transparent substrate; (c) forming a nitrogen doped carbon nanotube (CNₓ) layer on the transparent electrode; and (d) applying an oxide paste on the nitrogen doped carbon nanotube (CNₓ) layer to form the porous cathode electrode including the oxide semiconductor.

Another embodiment of the present invention provides a method for manufacturing a dye-sensitized solar cell that includes an upper transparent substrate; a transparent electrode formed on an inner surface of the transparent substrate; a porous cathode electrode formed on the transparent electrode and comprising an oxide semiconductor and a dye adsorbed on a surface of the oxide semiconductor; a counter electrode formed on a lower transparent substrate as an anode electrode part corresponding to the cathode electrode; and an electrolyte filled between the cathode electrode and the counter electrode, in which the method comprises (a) preparing the nitrogen doped carbon nanotube (CNₓ); (b) mixing an oxide paste with the nitrogen doped carbon nanotube (CNₓ); (c) forming a transparent electrode on the inner surface of the upper transparent substrate; and (d) applying the oxide paste having the nitrogen doped carbon nanotube (CNₓ) on the transparent electrode to form the porous cathode electrode including the oxide semiconductor.

According to various embodiments of the present invention, if the dye-sensitized solar cell is composed of the nitrogen doped carbon nanotube (CNₓ), the Fermi energy of the porous cathode which is composed of the n-type oxide semiconductor and nitrogen doped carbon nanotube may be increased, so that the solar cell may have a high open circuit voltage, as compared to those using the carbon nanotube (CNT). Moreover, efficiency and the electrical connectivity of device may be increased, when the longer nitrogen doped carbon nanotube is used.

### BRIEF DESCRIPTION OF THE DRAWINGS

The above and other aspects, features and advantages of the present invention will become apparent from the following description of preferred embodiments given in conjunction with the accompanying drawings, in which:

FIG. 1 is a cross sectional view illustrating the dye-sensitized solar cell according to a first embodiment of the present invention;

FIG. 2A is a schematic diagram illustrating a part of the dye-sensitized solar cell according to the first embodiment of the present invention;

FIG. 2B is a schematic diagram illustrating a part of the dye-sensitized solar cell according to a second embodiment of the present invention;

FIG. 2C is a schematic diagram illustrating a part of the dye-sensitized solar cell according to a third embodiment of the present invention;

FIG. 3A is an exemplary diagram illustrating gap states formed between titanium oxide (TiO₂) and the carbon nanotube (CNₓ) doped with nitrogen according to the present invention;

FIG. 3B is an exemplary diagram illustrating gap states formed between TiO₂ and the carbon nanotube (CNT) according to the present invention;

FIG. 4 is an exemplary graph illustrating I-V curve of the dye-sensitized solar cell according to the first embodiment of the present invention;

FIG. 5 is an exemplary graph illustrating I-V curve of the dye-sensitized solar cell according to the second embodiment and the third embodiment of the present invention;

FIG. 6 is a scanning electron microscope (SEM) image illustrating the structure laminated with TiO₂ on the transparent electrode of the dye-sensitized solar cell according to the present invention;

FIG. 7 is a SEM image illustrating the dye-sensitized solar cell according to the first embodiment of the present invention;

FIG. 8 is a SEM image illustrating the dye-sensitized solar cell according to the second embodiment of the present invention;

FIG. 9 is a flow chart of the method for manufacturing the dye-sensitized solar cell according to the first embodiment of the present invention;

FIG. 10 is a flow chart of the method for manufacturing the dye-sensitized solar cell according to the second embodiment of the present invention.

### DETAILED DESCRIPTION

The invention will now be described with reference to the drawing figures, in which like reference numerals refer to like parts throughout.

Prior to this, terms or words used in the specification and claims should not be construed as limited to a lexical meaning, and should be understood as appropriate notions by the inventor based on that he/she is able to define terms to describe his/her invention in the best way to be seen by others. Therefore, embodiments and drawings described herein are simply exemplary and not exhaustive, and it will be understood that various modifications and equivalents may be made to take the place of the embodiments.

An aspect of the present invention provides a method for increasing diffusion current by increasing the connectivity between nano-particles of TiO₂, or between TiO₂ and a transparent electrode for a dye-sensitized solar cell.

Specifically, embodiments of the present invention provide a method for improving the interface state between the carbon nanotube and the oxide semiconductor by doping the nitrogen to the carbon nanotube (CNT) modifying its Fermi energy as well as surface, and a method for improving an efficiency of the dye-sensitized solar cell by structurally controlling the interface state between the transparent electrode and the oxide semiconductor.

In the case of the dye-sensitized solar cell, an electron produced in the dye is transported to a particle of the oxide semiconductor, such as TiO₂, and the resulted electron is transported to a transparent electrode by a diffusion transport mechanism along particles of the oxide semiconductor.

During the process, the electrons are able to meet with an oxidized dye, or move to particles of the oxide semiconductor, and then may be recombined by an electrolyte. The process may further employ a carbon nanotube (CNT) having excellent thermal, electrical, and mechanical stability in order to more effectively performing said transport process.

For an experiment according to the present invention, it can be confirmed that current was increased by adding the carbon nanotube (CNT) layer between the layer of TiO₂ and the transparent electrode, in which the current was confirmed by measuring the properties of the solar cell. However, it can also be confirmed that open circuit voltage of the solar cell was decreased. It is generally known that open circuit voltage of the solar cell may be decreased because of Fermi energy equilibrium between the carbon nanotube (CNT) and TiO₂.

Therefore, the present invention suggests Fermi energy tuning by doping the carbon nanotube (CNT) with nitrogen in order to avoid the drop of open circuit voltage by using a carbon nanotube, i.e., in order to decrease the drop of open circuit voltage by increasing Fermi energy by a predetermined eV.

In growing of carbon nanotube (CNT) doped with nitrogen sources, doping could be confirmed through XPS. When doping with about 0.9 wt % of nitrogen, it can be confirmed that an alternative doping with nitrogen can be performed, and the properties about diffusion transport may be also good as compared to that of pure CNT.

Through the experiments of the present invention, the nitrogen doped carbon nanotube (CNₓ) having surface modification by doping with nitrogen was compared with the pure carbon nanotube (CNT) by application to various structures:
i) a first embodiment is a structure (Type I) of a cell further including a CNT layer or CNₓ layer between a transparent electrode and a TiO₂ layer in order to increase diffusion transport between the transparent electrode layer and the TiO₂ layer;
ii) a second embodiment is a structure (Type II) forming a cell by evenly mixing CNT or CNₓ with whole particles of TiO₂;
iii) a third embodiment includes forming a cell by mixing CNT or CNₓ with TiO₂ particles, in which CNT or CNₓ cannot be formed in the transparent electrode, but CNT-TiO₂ or CNₓ—TiO₂ could be formed at a predetermined distance from each other, so that a structure (Type III) could be formed, and CNT and CNₓ were compared for each types, in which the structure (Type III) has the decreased interface state effect between CNT or CNₓ and transparent conductive electrode.

As mentioned below, interface states by a surface dipole are formed on CNT and TiO₂, and if doping CNT with nitrogen, i.e., CNₓ, its Fermi energy will be increased by about 0.5 eV as compared to that of a pure CNT, so the energy level of a gap state generated between titanium oxides (TiO₂) will be increased. For this reason, it was confirmed that CNₓ has less effect on the drop of open circuit voltage as compared to that of CNT, which is not doped with nitrogen.

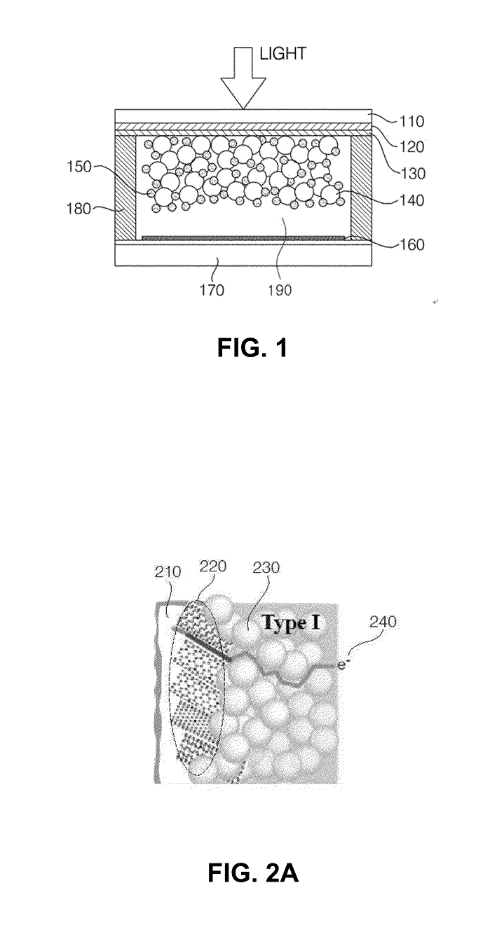

FIG. 1 is a cross sectional view illustrating the dye-sensitized solar cell according to the first embodiment of the present invention.

For the dye-sensitized solar cell according to the first embodiment of the present invention, the dye-sensitized solar cell includes an upper transparent substrate 110, a transparent electrode 120 formed on the inner surface of the upper transparent substrate 110, a porous cathode electrode including the oxide semiconductor 140 formed on the transparent electrode, in which the surface of the oxide semiconductor 140 is adsorbed with a dye 150, a counter electrode 160 as an anode electrode region corresponding to the cathode electrode, in which the counter electrode is formed on the lower transparent substrate 170, and an electrolyte filled between the cathode electrode and the counter electrode. A major characteristic is that the dye-sensitized solar cell further includes a nitrogen doped carbon nanotube (CNₓ) layer 130 between the transparent electrode and the porous cathode electrode.

Examples of the upper transparent substrate 110, which can be used in the present invention, include, but are not particularly limited thereto if the substrates should be transparent, a transparent inorganic substrate, such as quartz, glass, or a transparent plastic substrate, such as polyethylene terephthalate, polyethylene naphthalate, polycarbonate, polystyrene, polypropylene, and the like.

The transparent electrode 120, which is formed on the inner surface of the upper transparent substrate, can be formed by using ITO, FTO, ZnO—Ga₂O₃, ZnO—Al₂O₃, SnO₂—Sb₂O₃, and the like.

For the porous cathode electrode including the oxide semiconductor 140 absorbing a dye 150, which is formed on the transparent electrode in the present invention, the oxide semiconductor 140 may use TiO₂, and the oxide semiconductor may also be composed of one or more materials selected from the group consisting of TiO₂, In₂O₃, SnO₂, VO, VO₂, V₂O₃, and V₂O₅ according to the requirements of the present invention.

For the present invention, using Pt may form the counter electrode 160 as the anode electrode region corresponding to the cathode electrode, which is formed on the lower transparent substrate 170. In order to further increase the efficiency of the solar cell, the carbon nanotube (CNT) or the nitrogen doped carbon nanotube (CNₓ) may be used to form the counter electrode 160, but will not be limited to the above.

An electrolyte 190 filled between the cathode electrode and the counter electrode 160 is composed of p-type semiconductor material, and may use known materials, which are formed with a liquid electrolyte or a polymer gel.

A major characteristic of the first embodiment of the present invention is to include the nitrogen doped carbon nanotube (CNₓ) layer 130 between the transparent electrode and the porous cathode electrode. As set forth above, using nitrogen doped carbon nanotube (CNₓ) may have less effect on the drop of open circuit voltage of the solar cell, so the solar cell including the nitrogen doped carbon nanotube (CNₓ) has excellent connectivity between the oxide semiconductor 140 and the transparent electrodes 120, excellent open circuit voltage and conductivity, and may form a dye-sensitized solar cell having a high efficiency. A detailed method for manufacturing the solar cell will be described below.

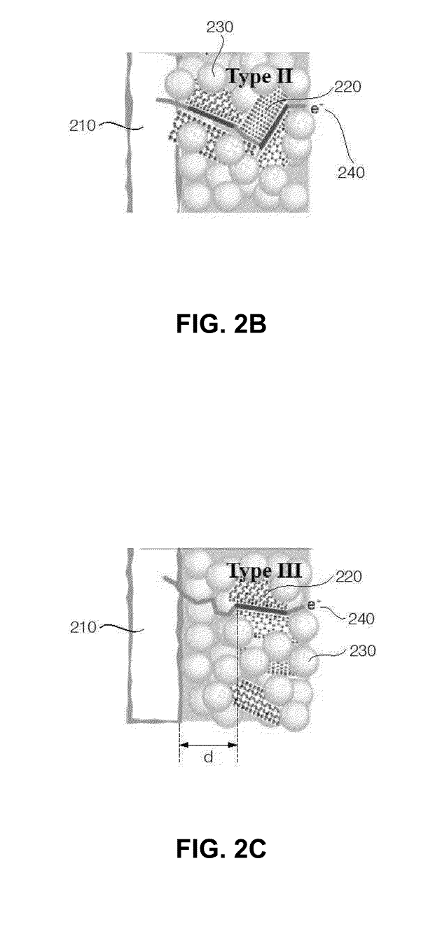

FIG. 2A is a schematic diagram illustrating a part of the dye-sensitized solar cell according to the first embodiment of the present invention.

FIG. 2A is a drawing of an enlarged part, which is composed of a transparent electrode 210, a nitrogen doped carbon nanotube (CNₓ) layer 220 and an oxide semiconductor 230, in which the drawing briefly expresses a pathway 240 of electron transfer.

FIG. 2B is a schematic diagram illustrating a part of the dye-sensitized solar cell according to the second embodiment of the present invention.

According to the second embodiment of the present invention, the dye-sensitized solar cell includes the upper transparent substrate, the transparent electrode 210 formed on the inner surface of the upper transparent substrate, the porous cathode electrode including the oxide semiconductor 230 formed on the transparent electrode, in which the surface of the oxide semiconductor is absorbed with a dye, the counter electrode as the anode electrode region corresponding to the cathode electrode, formed on the lower transparent substrate, the electrolyte filled between the cathode electrode and the counter electrode, in which a major characteristic of the dye-sensitized solar cell is that the porous cathode electrode includes the nitrogen doped carbon nanotube (CNₓ) layer 220.

In other words, in the second embodiment as compared to the first embodiment, the porous cathode electrode may be formed by mixing the oxide semiconductor with the nitrogen doped carbon nanotube (CNₓ) in order to directly combine the oxide semiconductor, such as TiO₂, with the nitrogen doped carbon nanotube (CNₓ) layer 220 without separately forming the nitrogen doped carbon nanotube (CNₓ) layer.

FIG. 2C is a schematic diagram illustrating a part of the dye-sensitized solar cell according to the third embodiment of the present invention.

According to the third embodiment of the present invention, it is a characteristic that the nitrogen doped carbon nanotube (CNₓ) layer 220 having predetermined distance d from the transparent electrode 210 may be formed for the dye-sensitized solar cell including the porous cathode electrode having the nitrogen doped carbon nanotube (CNₓ).

In other words, in the third embodiment as compared to the second embodiment, the nitrogen doped carbon nanotube (CNₓ) may not directly contact the transparent electrode, but there may be a predetermined distance d between the nitrogen doped carbon nanotube (CNₓ) and the transparent electrode. For the third embodiment, the layer of the oxide semiconductor may be firstly formed on the transparent electrode 210 by applying a pure oxide paste without the nitrogen doped carbon nanotube (CNₓ), and then an oxide paste with the nitrogen doped carbon nanotube (CNₓ) may be applied on the layer of the oxide semiconductor. As a result of the above process, the nitrogen doped carbon nanotube (CNₓ) layer 220 having predetermined distance d from the transparent electrode 210 may be formed.

For the third embodiment of the present invention, the distance d between the transparent electrode 210 and the nitrogen doped carbon nanotube (CNₓ) layer 220 may be 500 nm to 1000 nm.

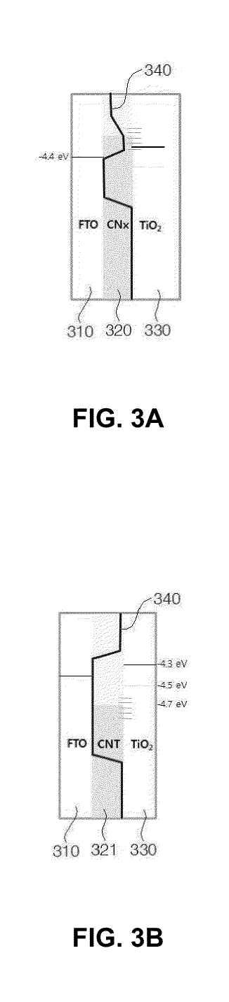

FIG. 3A is an exemplary diagram illustrating gap states formed between TiO₂ and the nitrogen doped carbon nanotube (CNₓ) according to the present invention and FIG. 3B is an exemplary diagram illustrating gap states formed between TiO₂ and the carbon nanotube (CNT) according to the present invention.

With reference to FIG. 3A and FIG. 3B, it can be confirmed that Fermi energy of gap states between the nitrogen doped carbon nanotube (CNₓ) and TiO₂ are higher than that of the carbon nanotube (CNT) without doping with nitrogen. Therefore, it can be seen that open circuit voltage of the nitrogen doped carbon nanotube (CNₓ) shows less decrease than that of the carbon nanotube without doping with nitrogen.

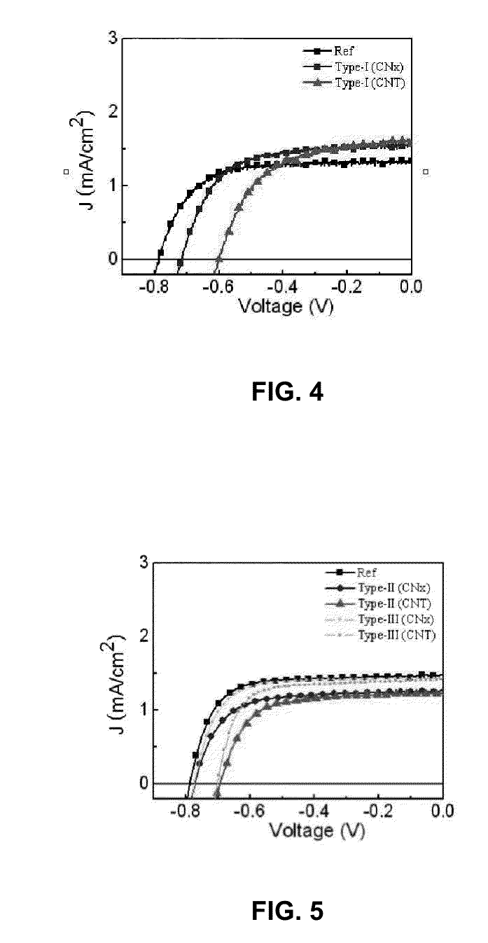

FIG. 4 is an exemplary graph illustrating I-V curve of the dye-sensitized solar cell according to the first embodiment of the present invention.

According to the first embodiment of the present invention, it is a characteristic that the solar cell further includes a nitrogen doped carbon nanotube (CNₓ) between the transparent electrode and the oxide semiconductor, and in a comparative example relating to the first embodiment, the solar cell including a pure carbon nanotube (CNT) layer is compared with the solar cell including the nitrogen doped carbon nanotube (CNₓ).

With reference to an I-V curve of FIG. 4, when laminating the layer of TiO₂ after laminating the layer of CNT or the layer of CNₓ on the transparent electrode, it could be confirmed that open circuit voltage was less decreased when laminating the nitrogen doped carbon nanotube (CNₓ) layer.

In the case of the above structure, since open circuit voltage decreases with the increase of CNT/CNₓ concentration, it could be known that gap states between CNT/CNₓ layer and the transparent electrode could affect the open circuit voltage. However, it could also be confirmed that when using the nitrogen doped carbon nanotube (CNₓ), the drop of open circuit voltage was significantly reduced than in the case of using CNT since Fermi energy is high. As a result, increased energy level of gap state reduces the recombination which also reduces the interface trap. However, the material resistance is larger for nitrogen doped carbon nanotube, so that current is similar with or without nitrogen doping.

FIG. 5 is an exemplary graph illustrating an I-V curve of the dye-sensitized solar cell according to the second embodiment and the third embodiment of the present invention.

For the second embodiment of the present invention, the cell is formed by mixing the nitrogen doped carbon nanotube (CNₓ) into spaces between the oxide semiconductors, and in a comparative example related to the second embodiment, the solar cell including the pure carbon nanotube (CNT) is compared with the solar cell including the nitrogen doped carbon nanotube (CNₓ).

In the case of the second embodiment and comparative example thereof, open circuit voltage could not be changed with the CNT/CNₓ concentration if mixing with a great quantity of CNT (CNₓ). It means that the above result follows Fermi energy equilibrium, and due to the improved connectivity, the CNT/CNₓ concentration can be a key factor for determining Fermi energy.

With reference to FIG. 5, it could be also confirmed that the solar cell formed by mixing the nitrogen doped carbon nanotube (CNₓ) having a high Fermi energy may less decrease open circuit voltage than that formed by mixing the pure carbon nanotube (CNT) in the second embodiment.

For the third embodiment of the present invention, when forming the solar cell by filling the nitrogen doped carbon nanotube (CNₓ) into spaces between the oxide semiconductors, a predetermined distance between CNₓ and the transparent electrode may be formed, and in a comparative example related to the third embodiment, the solar cell including the pure carbon nanotube (CNT) layer is compared with the solar cell including the nitrogen doped carbon nanotube (CNₓ).

In the above case described for the third embodiment, if mixing at least 0.2 wt % nanotube, the solar cell formed by mixing the nitrogen doped carbon nanotube (CNₓ) may also less decrease open circuit voltage than that formed by mixing the pure carbon nanotube (CNT), which may be determined by Fermi energy equilibrium.

For the second embodiment and the third embodiment, if using the above nanotube concentration, the drop of open circuit voltage was less decreased than that for the first embodiment. This is believed that effect of a gap state generated between the transparent electrode and the nanotube could be decreased by removing CNT (CNₓ) on the layer of TiO₂ around the transparent electrode.

It could be confirmed that improved connectivity between TiO₂ and transparent electrode as well as sensitizing effect may be also important as compared to the role of recombination site because of the increased current for the first embodiment.

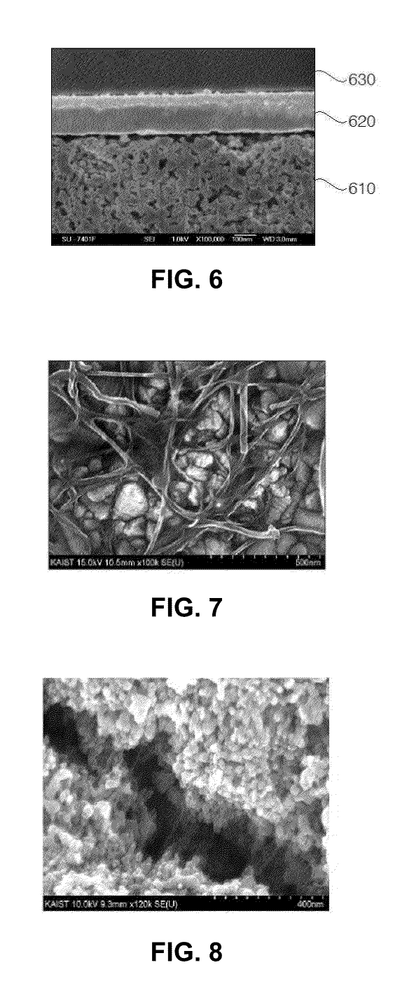

FIG. 6 is a scanning electron microscope (SEM) image illustrating the structure laminated with TiO₂ on the transparent electrode of the dye-sensitized solar cell according to the present invention.

FIG. 7 is a SEM image illustrating the dye-sensitized solar cell according to the first embodiment of the present invention.

FIG. 8 is a SEM image illustrating the dye-sensitized solar cell according to the second embodiment of the present invention.

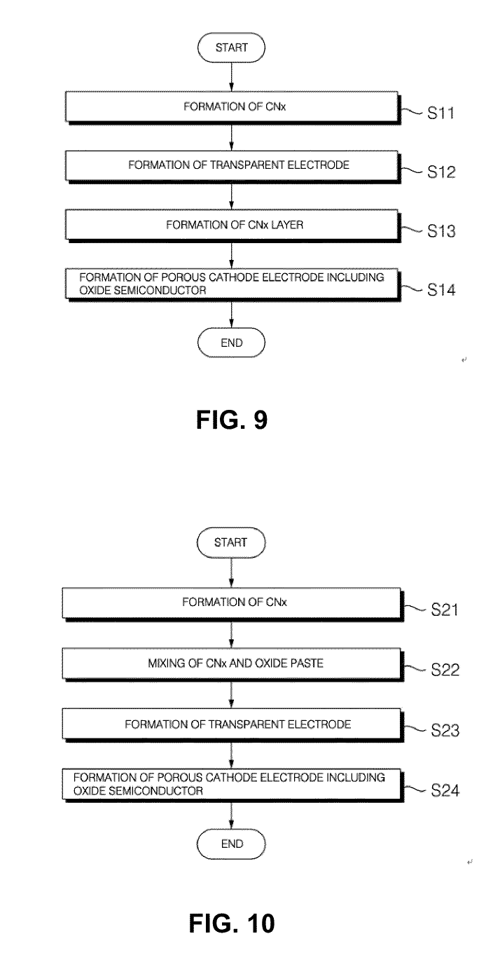

FIG. 9 is a flow chart of the method for manufacturing the dye-sensitized solar cell according to the first embodiment of the present invention.

According to the first embodiment of the present invention, there is provided a method for manufacturing a dye-sensitized solar cell, comprising an upper transparent substrate; a transparent electrode formed on an inner surface of the upper transparent substrate; a porous cathode electrode that is formed on the transparent electrode, and that includes an oxide semiconductor adsorbing a dye on the surface thereof; a counter electrode that is formed on a lower transparent substrate, and is an anode electrode part corresponding to the cathode electrode; and an electrolyte filled between the cathode electrode and the counter electrode, the method comprising: (a) preparing the nitrogen doped carbon nanotube (CNx); (b) forming a transparent electrode on the inner surface of the upper transparent substrate; (c) forming a nitrogen doped carbon nanotube (CNx) layer on the transparent electrode; and (d) applying an oxide paste on the nitrogen doped carbon nanotube (CNx) layer doped to form the porous cathode electrode including the oxide semiconductor.

Producing the nitrogen doped carbon nanotube (CNₓ) may be firstly performed (S11), and a method for preparing the nitrogen doped carbon nanotube (CNₓ) according to the present invention is as follows.

For the present invention, the nitrogen doped carbon nanotube (CNₓ) could be synthesized by a method of plasma-enhanced chemical vapor deposition (PECVD) on the silicon substrate using a thin Fe film as a catalyst under an atmosphere of CH₄ gas, H₂ and/or N₂ gas.

Firstly, the substrate containing the catalyst may be transferred to a PECVD chamber, the chamber may be heated to 710° C. under a pressure of 1⁻¹⁰ Torr, and a quantity of nitrogen/hydrogen gas may injected into the chamber by a controller for injecting in bulk.

After the pressure of the chamber reaches 12 Torr, plasma may be heated by a micro wave, and heating nitrogen/hydrogen plasma may be continued for 1 min. A temperature should be continuously raised to 850° C. during the above preheating process of the plasma, and a pressure should be raised to 22 Torr. The temperature and pressure should be maintained at those values until the end of overall processes.

Next, methane may be added after 1 min, the carbon nanotube is able to increase on the region of catalyst. N₂ concentration in gases injected by comparison of CH₄ source may be changed in order to control the level of nitrogen doping. Accordingly, the nitrogen doped carbon nanotube (CNₓ) may be increased until the same amount as N₂ and CH₄ is reached and the time of increasing is 30 sec.

However, the present invention is not limited to the above processes, but any process can be used if it can produce a paste of the nitrogen doped carbon nanotube (CNₓ).

In addition, the present invention can be used to form the nitrogen doped carbon nanotube (CNₓ) layer or the carbon nanotube (CNT) by forming a polarity on the surface through tetraoctylammonium bromide (TOAB) doping.

Excellent connectivity between the transparent electrode and the oxide semiconductor may be achieved by using the nitrogen doped carbon nanotube (CNₓ) or the carbon nanotube (CNT) through the above mentioned TOAB doping.

Since then, forming the transparent electrode on the inner surface of the upper transparent substrate may be performed (S12).

The transparent electrode may be formed by using a material, which has a definite translucency of solar light and conductivity, and an example of those materials includes ITO, FTO, ZnO—Ga₂O₃, ZnO—Al₂O₃, SnO₂—Sb₂O₃, and the like.

Since then, forming the nitrogen doped carbon nanotube (CNₓ) layer on the transparent electrode may be performed (S13).

In addition, the nitrogen doped carbon nanotube (CNₓ) layer formed by a paste of the nitrogen doped carbon nanotube (CNₓ) may be formed in a pattern of a spot shape, linear shape and area shape by using one selected from a group consisting of a doctor blade coating method, a screen printing method, a spraying method, a spin coating method, a painting method, and the like. The thickness may be within the range of 10 nm to 1 mm. Specifically, when forming a pattern of area shape, it can be possible to coat a large area of less 1 m² by the spraying method.

Since then, forming the porous cathode electrode including the oxide semiconductor may be performed (S14) by applying the oxide paste on the nitrogen doped carbon nanotube (CNₓ) layer, in which the oxide paste may be laminated by the spin coating method for forming the porous cathode electrode including the oxide semiconductor. However, it may not be limited to the spin coating and any method can be used if it can form a layer of the porous oxide semiconductor.

A method for manufacturing the paste of the oxide semiconductor according to experimental example of the present invention will briefly describe in the following.

TiO₂ powder: hydroxypropyl cellulose: water were mixed at 2.4 g: 1.35 g: 5.4 g, respectively. The resulted mixture was then mixed with 0.2 ml of acetylacetone, was mixed with 0.6 g of a dry powder, 2 ml of water, and 0.02 ml of acetylacetone at 90° C., and was mixed with 0.01 ml of Triton X-100 as a dispersing agent to form the oxide semiconductor paste.

However, the present invention is not limited to the above processes, and any process can be used if it can form the oxide semiconductor paste.

FIG. 10 is a flow chart of the method for manufacturing the dye-sensitized solar cell according to the second embodiment of the present invention.

According to the second embodiment of the present invention, there is provided a method for manufacturing a dye-sensitized solar cell, comprising an upper transparent substrate; a transparent electrode formed on an inner surface of the transparent substrate; a porous cathode electrode that is formed on the transparent electrode, and that includes an oxide semiconductor adsorbing a dye on the surface thereof; a counter electrode that is formed on a lower transparent substrate, and is an anode electrode part corresponding to the cathode electrode; and an electrolyte filled between the cathode electrode and the counter electrode, the method comprising: (e) preparing the nitrogen doped carbon nanotube (CNₓ); (f) mixing an oxide paste with the nitrogen doped carbon nanotube (CNₓ); (g) forming a transparent electrode on the inner surface of the upper transparent substrate; and (h) applying the oxide paste having the nitrogen doped carbon nanotube (CNₓ) on the transparent electrode to form the porous cathode electrode including the oxide semiconductor.

According to a third embodiment of the present invention, the step of (h) further comprises: applying an oxide paste without the nitrogen doped carbon nanotube (CNₓ) on the transparent electrode; and applying the oxide paste with the nitrogen doped carbon nanotube (CNₓ) on the oxide paste without the nitrogen doped carbon nanotube (CNₓ) to form the porous cathode electrode including the oxide semiconductor.

In other words, firstly preparing the nitrogen doped carbon nanotube (CNₓ) may be performed in the second embodiment of the present invention (S21). The method for manufacturing the nitrogen doped carbon nanotube (CNₓ) will be omitted since the method was described above.

After this, mixing the nitrogen doped carbon nanotube (CNₓ) with the oxide semiconductor paste may be performed (S22).

In other words, the paste of nitrogen doped carbon nanotube (CNₓ) manufactured by using the method for manufacturing the nitrogen doped carbon nanotube (CNₓ) as mentioned above may be mixed with the oxide paste manufactured by using the method for manufacturing the oxide paste as mentioned above.

Then, forming the transparent electrode on the inner surface of the transparent substrate may be performed (S23), the oxide paste including the nitrogen doped carbon nanotube (CNₓ) may be applied on the transparent electrode, and then forming the porous cathode electrode including oxide semiconductor may be performed (S24).

For the third embodiment of the present invention, however, for forming the porous cathode electrode including the oxide semiconductor (S24), the oxide paste without the nitrogen doped carbon nanotube (CNₓ) may be firstly applied, and then the oxide paste with the nitrogen doped carbon nanotube (CNₓ) may be applied to form the nitrogen doped carbon nanotube (CNₓ) having predetermined distance from the transparent electrode.

In conclusion, for the first embodiment to the third embodiment of the present invention, in order to manufacture the solar cell, CNT and CNₓ may be located on the transparent electrode by electrochemically laminating, and TiO₂ paste may be coated by spin coating (first embodiment), or after evenly mixing CNT/CNₓ with the paste, the resulted mixture may be laminated by the spin coating (second embodiment and third embodiment). Since then, the materials deposited may be vaporized by annealing at 500° C., and the counter electrode may be formed by pt solution and combined with an electrolyte. I-V curve of the resulted solar cell may be measured by using a solar simulator, and the impedance of the solar cell may be measured to confirm the properties of the cell. The results show that the efficiency of a dye-sensitized solar cell formed by using the nitrogen doped carbon nanotube (CNₓ) was excellent.

While the present invention has been described with reference to preferred embodiments, it will be understood by those skilled in the art that various modifications and variations may be made therein without departing from the scope of the present invention as defined by the appended claims.

What is claimed is:

1. A dye-sensitized solar cell, comprising:
an upper transparent substrate;
a transparent electrode formed on an inner surface of the upper transparent substrate;
a porous cathode electrode formed on the transparent electrode and comprising an oxide semiconductor and a dye adsorbed on a surface of the oxide semiconductor;
a counter electrode formed on a lower transparent substrate as an anode electrode part corresponding to the cathode electrode; and
an electrolyte filled between the cathode electrode and the counter electrode,
wherein the dye-sensitized solar cell further comprises a nitrogen doped carbon nanotube (CNₓ) layer between the transparent electrode and the porous cathode electrode.

2. A dye-sensitized solar cell, comprising:
an upper transparent substrate;
a transparent electrode formed on an inner surface of the upper transparent substrate;
a porous cathode electrode formed on the transparent electrode and comprising an oxide semiconductor and a dye adsorbed on a surface of the oxide semiconductor;
a counter electrode formed on a lower transparent substrate as an anode electrode part corresponding to the cathode electrode; and
an electrolyte filled between the cathode electrode and the counter electrode,
wherein the porous cathode electrode comprises a nitrogen doped carbon nanotube (CNₓ).

3. The dye-sensitized solar cell according to claim 2, wherein the nitrogen doped carbon nanotube (CNₓ) is formed at a predetermined distance from the transparent electrode.

4. The dye-sensitized solar cell according to claim 1, wherein the oxide semiconductor absorbing the dye is TiO₂.

5. A method for manufacturing a dye-sensitized solar cell including an upper transparent substrate, a transparent electrode formed on an inner surface of the upper transparent substrate, a porous cathode electrode formed on the transparent electrode and including an oxide semiconductor and a dye adsorbed on a surface of the oxide semiconductor, a counter electrode formed on a lower transparent substrate as an anode electrode part corresponding to the cathode electrode, and an electrolyte filled between the cathode electrode and the counter electrode, the method comprising:
(a) preparing the nitrogen doped carbon nanotube (CNₓ);
(b) forming the transparent electrode on the inner surface of the upper transparent substrate;
(c) forming the nitrogen doped carbon nanotube (CNₓ) layer on the transparent electrode; and
(d) applying an oxide paste on the nitrogen doped carbon nanotube (CNₓ) layer to form the porous cathode electrode including the oxide semiconductor.

6. A method for manufacturing a dye-sensitized solar cell including an upper transparent substrate, a transparent electrode formed on an inner surface of the transparent substrate, a porous cathode electrode formed on the transparent electrode and including an oxide semiconductor and a dye adsorbed on a surface of the oxide semiconductor, a counter electrode formed on a lower transparent substrate as an anode electrode part corresponding to the cathode electrode, and an electrolyte filled between the cathode electrode and the counter electrode, the method comprising:
(a) preparing a nitrogen doped carbon nanotube (CNₓ);
(b) mixing an oxide paste with the nitrogen doped carbon nanotube (CNₓ);
(c) forming the transparent electrode on the inner surface of the upper transparent substrate; and
(d) applying an oxide paste comprising the nitrogen doped carbon nanotube (CNₓ) on the transparent electrode to form the porous cathode electrode comprising the oxide semiconductor.

7. The method according to claim 6, wherein the step of (d) further comprises:
applying an oxide paste without the nitrogen doped carbon nanotube (CNₓ) on the transparent electrode; and
applying the oxide paste with the nitrogen doped carbon nanotube (CNₓ) on the oxide paste without the nitrogen doped carbon nanotube (CNₓ) to form the porous cathode electrode comprising the oxide semiconductor.

8. The method according to claim 5, wherein the step of (a) comprises preparing the nitrogen doped carbon nanotube (CNₓ) by a PECVD method using Fe catalyst under an atmosphere of CH₄, H₂ and N₂ gas.

9. The method according to claim 5, wherein the step of (d) comprises forming the porous cathode electrode comprising the oxide semiconductor by laminating the oxide paste through a spin coating method.

10. The method according to claim 5, wherein the oxide semiconductor is TiO₂.

11. The method according to claim 6, wherein the step of (a) comprises preparing the nitrogen doped carbon nanotube (CNₓ) by a PECVD method using Fe catalyst under an atmosphere of CH₄, H₂ and N₂ gas.

12. The method according to claim 6, wherein the step of (d) comprises forming the porous cathode electrode comprising the oxide semiconductor by laminating the oxide paste through a spin coating method.

13. The method according to claim 6, wherein the oxide semiconductor is TiO₂.
